(19) United States
(12) Patent Application Publication
(10) Pub. No.: US 2002/0161700 A1
(43) Pub. Date: Oct. 31, 2002

(54) Mechanism to provide regression test packages for fulfillment systems

(75) Inventors: Michael J. Ernst, Boeblingen (DE); Kathleen Wolfram, Luedenscheid (DE)

Correspondence Address: William A. Kinnaman, Jr., IBM Corporation, 2455 South Road M/S P386, Poughkeepsie, NY, 12601, US

(73) Assignee: INTERNATIONAL BUSINESS MACHINES CORPORATION, ARMONK, NY

(21) Appl. No.: 10/079,207

(22) Filed: Feb. 19, 2002

(30) Foreign Application Priority Data
Feb. 22, 2001 (DE) 01104204.1

(51) Int. Cl. G06F 17/60; H04L 1/22; H04B 1/74; H02H 3/05; H05K 10/00; H03K 19/003

(52) U.S. Cl. 705/38; 714/25

(57) ABSTRACT

Disclosed are a method and system for performing regression tests in a computer-based product or service fulfillment management system. Generation of regression test packages is accomplished by collecting fulfillment activity data, defining a set of criteria to assess the collected fulfillment activity data, evaluating the collected fulfillment activity data based on the set of criteria, and defining objectives for the generation of regression test packages. Based on these objectives, regression test packages are generated and a regression test is run using these test packages. Thus regression test packages can be provided automatically and dynamically preferably based on actual fulfillment data from a general ledger, according to several criteria such as occurrences, revenue/profit of order/contract types, material classes, customer classes, etc. In particular, those regression tests deal with the specific problem of assessing the underlying fulfillment procedures and of keeping them up-to-date and thus to provide regression test packages which dynamically and automatically adapt to a changed real world environment.

### BACKGROUND OF THE INVENTION

1. Field of the Invention

The invention generally relates to computer-based or computer-assisted product or service fulfillment management systems and, more specifically, to regression testing in such a data processing system environment. Even more specifically the invention concerns generation of regression test packages for those fulfillment management systems.

2. Description of the Related Art

In the field of sales, fulfillment management like order fulfillment etc. is required to guarantee that products, premiums, or prizes find their way to the right customers. A modern fulfillment process, particularly with the rise of e-commerce, is more important than ever to a company.

According to Stanley J. Fenvessy, the author of Fenvessy on Fulfillment, fulfillment consists of nine major steps:

1. Order forms and instructions: On an e-commerce site, this includes selecting merchandise, transferring it to an online shopping cart, and filling out shipping information. For an incentive program, it includes rules on qualifying for prizes.

2. Order receipt: By mail, telephone, or online. Includes initial clerical processing and data entry;

3. Credit approval: For consumer purchases, includes credit card authorization or check clearance;

4. List maintenance: Accumulation of customer demographics for marketing;

5. Inventory control: Management of redemption trends so that merchandise is always available, yet stock levels are not so high that inventory costs are excessive;

6. Billing: Production of initial bill (if customer hasn't prepaid) and follow-up reminders;

7. Reports: Production of marketing, merchandising, financial and operating control reports;

8. Order filling and shipping: Receiving, stocking, picking, packing, and shipping products; and

9. Customer service: Handling inquiries, complaints, and merchandise returns.

However, for e-commerce and consumer promotions, probably more thousands, if not millions, of pieces of merchandise are required. Therefore, sufficient warehouse space and computer systems are a major issue.

In order to build up a fulfillment process, at least the following policies should be established and the following decisions be made:

1. If a call center to receive orders shall be run, the level of service that shall be provided has to be determined. It is neither economical nor practical for all calls to be answered without a delay. Thus an acceptable level of customers who will be inconvenienced has to be determined. For example, some known fulfillment centers aim to handle 90 percent of calls (within 20 seconds) without placing customers on hold or into voice mail;

2. A decision has to be made who will process orders and how they will be processed. Steps include downloading orders from the Internet or extracting orders from envelopes, sorting and batching, processing checks and credit cards, and printing;

3. Customer service policies have to be established. Under what conditions will refunds or merchandise credits be offered? How will orders not containing sufficient payment be handled?

4. A picking system has to be chosen. There are three major ways for warehouse workers to physically pick orders off the shelves. A first way to implement such a picking system is single order picking. Here each item on an order is picked from various locations by a single worker. Another way is multiple picking. Here several orders are picked at once, using a truck or cart. Yet another way is sequential zone picking. Here the order moves by conveyer belt or cart from one zone to another and is assembled at a final packing point.

5. Packing materials have to be chosen. Carton sizes will depend on the product sizes and typical order size. Cushioning materials can include newspaper, tissue, Styrofoam pellets, or bubble wrap. Optimal choices depend on cost, weight, and the desired degree of protection against damage.

6. A relationship with a shipper has to be established. Determine pickup schedules, and find out what the shipper's packaging requirements are.

7. Finally, a way to capture customer order data has to be developed. Data might include a source code for how the customer found you, customer telephone number, date of first order, total orders to date, total order value, and types of products ordered.

In addition, a particular field needing a fulfillment process, is supply chain management. A supply chain is all inter-linked resources and activities needed to create and deliver products and services to customers. In the truest sense, the supply-chain spans from the point where natural resources are removed from the earth to the point where they are replaced in the earth. Thus supply chain management embraces coordinating, scheduling and controlling procurement, production, inventories and deliveries of products and services to customers. Supply chain management includes all the steps in administration, operations, logistics department(s), including processing information from customers to suppliers.

A software based approach for fulfillment requirements management, such as coordinating product information from the marketing of products to the ordering of products to the production of products, is disclosed in U.S. Pat. No. 6,014,637, assigned to the present assignee. Known fulfillment management scenarios particularly describe the coordination of products offered, product availability, and order processing to get a product from the offering stage to a consumer through final delivery of the product to the consumer. That approach provides an object oriented framework mechanism having certain core functions which interact with extensible functions provided by a framework consumer. The architecture of the described framework allows a user to determine the conditions and parameters that apply to a specific environment while allowing a programmer to interact with the framework with an interface that is consistent regardless of the specific combination of parameters specified in the fulfillment requirements manager. The extensible functions allow new fulfillment requirements environments to be easily implemented using the framework.

In view of the above rather complex fulfillment processes, most of the known fulfillment systems are information technology (IT) based. Thus there is a great need to have a test scenario which enables one to perform regression tests on different parts of or even a whole fulfillment process in such IT environments. These regression tests require special test cases in order to detect shortcomings of the underlying fulfillment system. Thereupon, IT supported customer relationship management (CRM) or the above mentioned IT supported call centers are more and more involved in generation of test cases.

A method of regression testing in a related technical field, namely in the field of regression testing of transaction based software applications during the development and other life cycle phases of the software, is disclosed in U.S. Pat. No. 6,061,643. Regression tests comprised of test cases containing test data describe the target test at a functional or behavioral level and execute a regression test at a physical level. The functional level accommodates changes to the transaction such as the moving of text fields to other locations within a frame or the changing of the presentation of particular fields from one form to another. A test operator performs a manual test and simultaneously records the test. The test data is in a robust functional description of the transaction such that physical modifications to the transaction during software development preserve the viability of the test data for execution in the modified transaction. A particular component facilitates the creation of test cases for transactions by monitoring the performance of the test in the transaction itself A test report is compared with a control test report to verify the lack of regression of the transaction. Accordingly, changes to the transaction therefore shall not result in unusable test data.

So far, existing business process descriptions of a fulfillment process are to be supported by a software system as in the above described prior art approach. In the beginning of an evaluation of a fulfillment process there are no empirical data on which to rely. Once this data is available, it is often ignored. Regression test packages are used as defined in the first place due to time or other restrictions. At best they are enriched and enhanced by added functions, getting more and more.

The prior art approaches therefore have in common the drawback that no empirical data is used for a regression test on the above described fulfillment systems and thus the real world link is missing. In contrast to the field of software development where most of the changes made on existing computer programs are subject to respective customer inputs, changes of the test packages as proposed herein are mainly driven by the usage of the fulfillment management system itself.

In addition, the prior art approaches do not address the fact that test cases have to change dynamically in order to meet the dynamic changes of the underlying fulfillment management environment over time.

### SUMMARY OF THE INVENTION

It is therefore an object of the present invention to provide a computer-based or computer-assisted mechanism for an improved fulfillment management system.

It is another object to provide improved regression testing in a fulfillment management system.

It is yet another object to provide a regression test mechanism oriented to real world empirical data.

It is yet another object to provide a mechanism that enables fast, dynamically adapting and efficiently working regression tests in such a fulfillment management environment.

A further object is to provide a fast, dynamically and/or efficiently operating or processing fulfillment management system.

The above objects are achieved by the features of the independent claims. Advantageous embodiments are subject matter of the subclaims.

The proposed mechanism particularly includes the steps of collecting fulfillment activity data, defining a set of criteria to assess the collected fulfillment activity data, evaluating the collected fulfillment activity data based on the set of criteria, and defining objectives for the generation of regression test packages. Based on these objectives, regression test packages are generated, or assembled or combined, e.g. by using existing test cases known from previous regression tests conducted for previous product versions, and finally one or more regression tests run using these test packages.

The invention therefore allows one to generate regression test packages for fulfillment systems automatically and dynamically and thus accordingly to run regression tests automatically, preferably based on actual fulfillment data from a general ledger, according to several criteria such as occurrences, revenue/profit of order/contract types, material classes, customer classes, etc. The general ledger usually is a central database containing all merchandise information, in particular information relating to previous or pending business or merchandise transactions.

In addition, the invention allows in a fulfillment scenario, that regression tests can deal with the specific problem of assessing the underlying fulfillment procedures and of keeping them up-to-date and thus to provide regression test packages which dynamically and automatically adapt to a changed real world environment.

The invention further concerns a fulfillment system comprising a regression test package generator that dynamically generates packages accordingly.

Due to the used criteria, the selection of test cases can be limited to a minimum number.

The mechanism has the advantages that it deals with facts (i.e. real production data) rather than assumptions from early project stages, that it keeps the volume of the regression test package to an absolute minimum according to defined objectives what to cover by the regression test, that it allows a value based assessment of the regression test status rather than an assessment based on pure test case numbers, and that it allows the improvement of the fulfillment process as such by validating projected assumptions of volumes to be processed and by identifying clusters and relations.

Further, analysis of the evaluated criteria allows the provision of regression test scenarios which cover an actual production system in the best possible way under given objectives, such as number of test cases, percentage of coverage. Due to the fact that the analysis is done on a general ledger (database), the regression test package is not static but dynamic in the sense that always the most current data is evaluated.

The calculated data also allows for measuring the test progress, e.g. by means of a status report, which extends the ordinary “number of test cases processed” by statements about the real content such as percentage of orders/revenue covered.

The mechanism can also be applied to measure the fulfillment systems as such in order to determine and eliminate obsolete function blocks and, enriched by performance data which is not in the general ledger but is provided from other information technology (IT) databases, to optimize the systems according to criteria such as optimal support of critical, e.g. most revenue relevant order types.

In addition, the mechanism when applied to projected enhancements and modifications of the underlying fulfillment system can also be used to estimate and track implementation effort and verification of assumptions.

The principles described beforehand and hereinafter are applicable to any environment where fulfillment systems are defined, maintained and executed. IBM's fulfillment system for OS/390 Entitled Software (ESW) is representative of that area.

The proposed mechanism can be particularly applied in product or service fulfillment scenarios where products have relatively short life-cycles, as in the field of software distribution, where there are a multitude of product versions, as in the automotive industry, or where product development is over a number of development levels or stages.

### BRIEF DESCRIPTION OF THE DRAWINGS

In the following, the present invention is described in more detail by way of embodiments from which further features and advantages of the invention become evident.

In the drawings:

FIG. 1 is an overview block diagram of a fulfillment regression test environment illustrating the underlying concept of the present invention;

FIG. 2 is a flow diagram illustrating a preferred embodiment of the mechanism proposed by the invention;

FIG. 3 is a block diagram illustrating a regression test package generator in accordance with the invention; and

FIG. 4 is a flow diagram further illustrating the regression test package generator depicted in FIG. 3.

### DETAILED DESCRIPTION OF THE PREFERRED EMBODIMENT

In the following, the concept, process flow, production data analysis, test case catalog as well as samples of additional applying environments are illustrated.

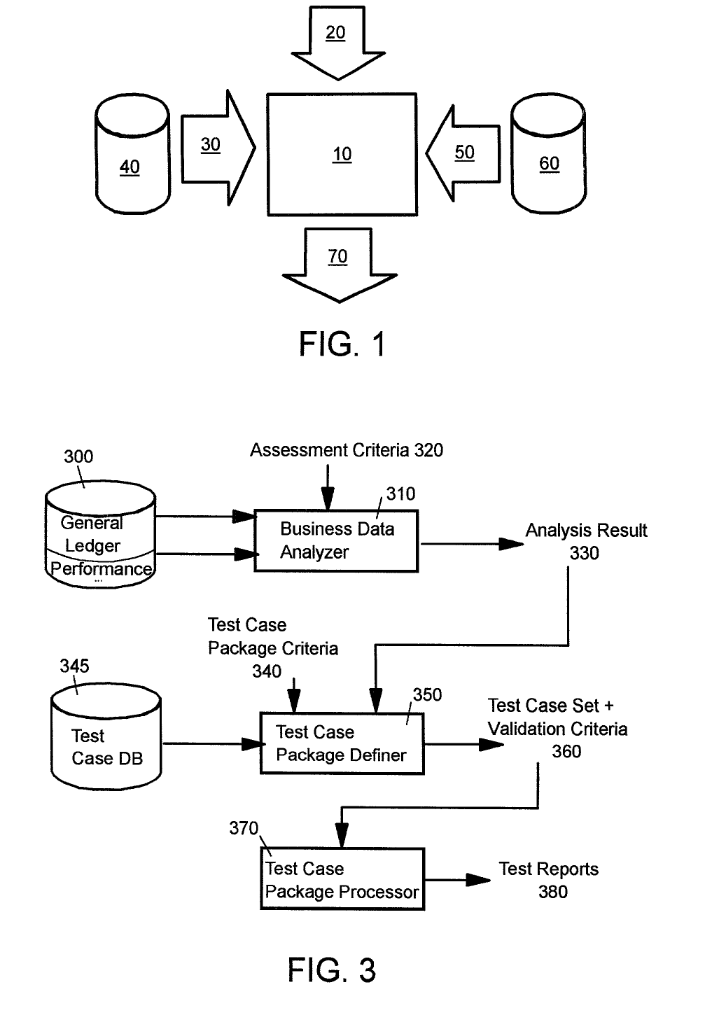

FIG. 1 shows the basic data flow in a fulfillment management environment in order to illustrate generation 10 of regression test packages in accordance with the present invention. The generation of the test packages 10 is based upon predefined test criteria 20 and pre-analyzed production data 30 gathered from a general ledger 40. The production data can use performance/maintenance/error information for the underlying business or merchandise transactions. From a test case catalog 60, which contains existing test cases used previously for testing a former product release (product version ‘n’) as described in more detail hereinafter, the test cases used for the test packages are selected 50. The general ledger and the test case catalog, in the shown embodiment, are stored in a database server, e.g. an IBM DB2 database. After setup of a regression test package, a regression test is run 70 on the underlying fulfillment system.

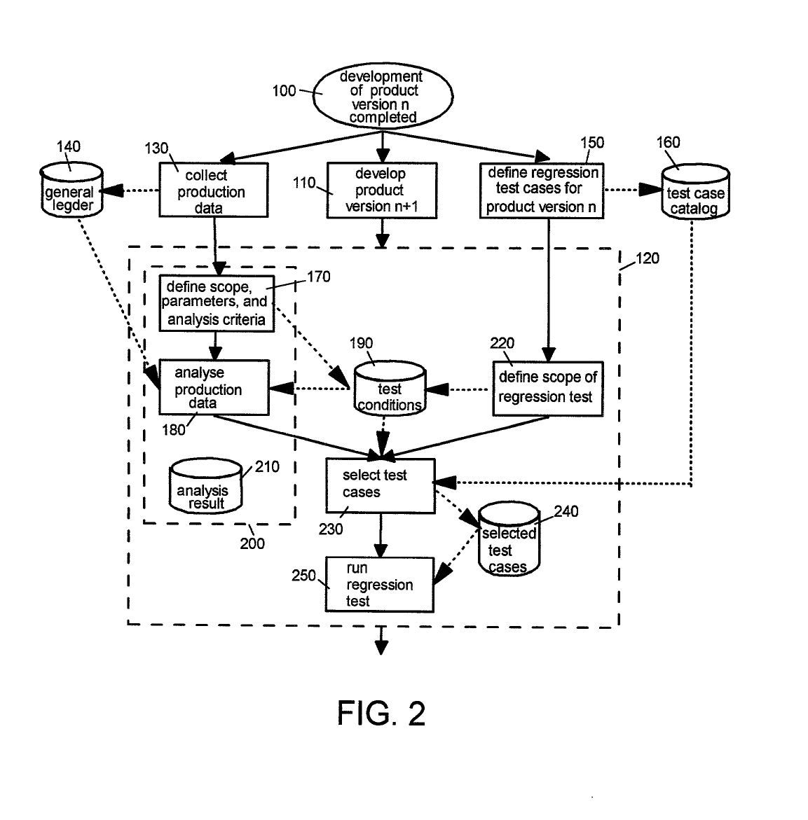

A preferred embodiment of the mechanism of the invention will now be described in more detail referring to the flow diagram depicted in FIG. 2. The mechanism starts with a scenario where development of a product version n of an arbitrary (software or hardware) product is completed 100. A new version n+1 of that product is going to be developed 110 and shall be tested by way of a regression test 120. It is further assumed that, for product version n, production data is collected 130 and stored in a general ledger 140. Further, it is assumed that for product version n regression test cases are already defined 150 and stored in a test case catalog 160. In other words, as shown in FIG. 1, the proposed mechanism uses data provided by a general ledger and a test case catalog, both stored on the mentioned database server.

It is noted that the functional features of the mechanism according to the invention are separated by a dotted line 120 from the depicted other features known in the prior art.

The mechanism for generating regression test packages for new product version n+1 thus comprises the following steps:

1. Collect 130 all fulfillment activities (here: orders and contracts) in the general ledger database 140; this step is performed outside the regression test package (RTP) generator 120 and is part of step 30 in FIG. 1;

2. If applicable, enrich this data with data from the performance/maintenance/error database, from the customer satisfaction database (can be made available as additional assessment criteria for the regression test or other analytical work); this step is performed outside the RTP generator and is part of step 30 in FIG. 1;

3. Define 170 a set of criteria to assess the data, i.e. the scope, parameters and analysis criteria for a following analysis 180 of the production data, e.g. the number of occurrences, the amount of revenue/profit, the number of processing errors, a customer satisfaction, etc., that is stored in a test conditions database 190; this step is performed within a business data analyzer 200 and is part of step 20 in FIG. 1;

4. Analyze the provided production data of a defined period of time according to the given criteria, e.g. the number of occurrences, amount of revenue/profit etc. per order type, the number of occurrences etc. per customer class, the number of occurrences etc. per material class, and store this data as base data for regression test package definition/tracking (this database can also be used for the other analyzing functions such as problem determination by clustering independent error descriptions) and provide analysis results to an analysis results database 210; this step is performed within the business data analyzer 200 and is part of step 30 in FIG. 1;

5. Define 220 the objectives for the regression test package, i.e. the scope of the regression test, e.g. the number of overall test cases, percentage of coverage of order types (e.g. the test cases should reflect 80% of all order types used in production), percentage of revenue/profit (e.g. the test cases should reflect the order types, customer types, etc. that do 80% of the revenue/profit), error-prone sections (e.g. the test cases should contain all processes which produced more than 5% errors, which have a customer satisfaction less than 90) etc. (part of step 20 in FIG. 1);

6. From the provided test case database 160, a regression test package generator 230 combines appropriate test scenarios based on the set of criteria 170 stored in test conditions database 190, the analysis results 210 and the defined scope 220 of the regression test, e.g. test scenarios consisting of order/contract type, customer, material, etc. (the total number of test cases can be minimized by finding a minimum of test case scenarios covering all objectives or can be given as another objective, e.g. 20, 50 test cases), and stores the selected test cases in a selected test cases database 240 (part of step 50 in FIG. 1);

7. Based on the selected test cases stored in database 240, a regression test is run 250 wherein, during the test, current status reports stating the total number of test cases started, processed, in error etc. can be improved by providing the actual data according to defined objectives: e.g. the current test status covers 60% of all business scenarios, 85% of the revenue from last year's production etc. (part of step 70 in FIG. 1).

The functional units of the above mentioned regression test package generator are now described in more detail referring to FIG. 3. As mentioned beforehand, a database 300, the so-called general ledger, contains performance data of product version n and additional business data for that product (according to above steps a) and b)). This data stored in database 300 is input to and processed by a business data analyzer 310 (acc. to above steps c) and d)), together with certain assessment criteria 320 like turnover figures achieved with the product. The analysis results 330, together with the mentioned test case package criteria 340 and existing test cases loaded from the mentioned test case database 345, are then input to and processed by a test case package definer 350 (acc. to above steps e) and f)). The test case package definer 350 delivers a set of test cases and certain validation criteria 360. This data, together with the selected test cases gathered from the test case database 345, is input to a test case package processor 370 (acc. to above step g)) that performs the regression test based on the selected package of test cases and delivers a test report 380.

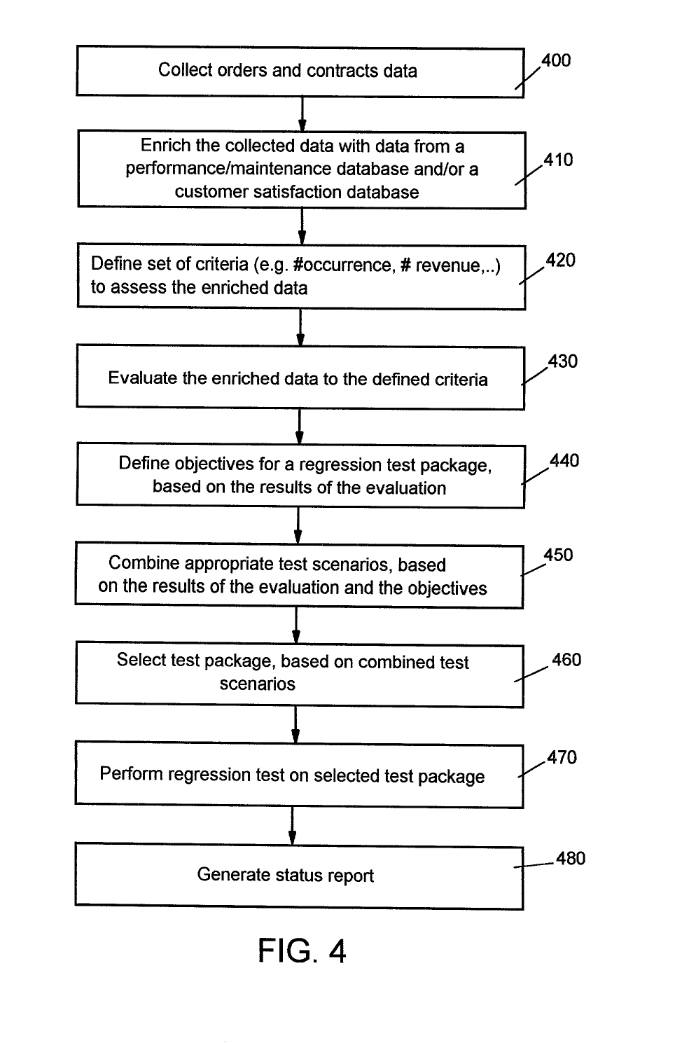

The data flow of the regression test package generator depicted in FIG. 3 is now described referring to the flow diagram depicted in FIG. 4. From the general ledger orders and contracts data is collected 400 and enriched 410 with other data, e.g. business performance data for these business transactions. Further, a set of criteria, e.g. the number of occurrences, the amount of revenue etc. are defined 420 to assess the enriched data. Then the enriched data is evaluated 430 based on the defined criteria. Thereafter, objectives for a regression test package are defined 440. Based on the defined objectives and the results of the evaluation, appropriate test scenarios are combined 450 from existing test cases for the previous version n of the product. From the selected test cases a test package is formed 460 and a regression test performed 470 based on that test package. During the regression test, a status report is generated 480.

In the following, applicability of the invention to other environments than the beforehand described is illustrated by way of exemplary embodiments. At the end, an application scenario in the field of car manufacturing and sales is described in more detail.

The above described mechanism according to the invention can be applied to several environments which deal with products whose life cycles comprise several product versions; provide information about the usage of the product; or reflect business processes related to products.

Exemplary environments are:

1. Fulfillment products: This scenario is already described beforehand. The fulfillment product is developed over a longer period of time. Production data is stored in a general ledger database. Test cases can be selected according to the relevance to specific products, to revenue, etc. Production data analysis using e.g. volumes and production errors/problems can also be used as input for product improvement.

2. Software products in general: The mechanism can be applied to any product test environment. Therefore it can also be implemented in test support products.

3. Car manufacturing: The scenario here is set up by cars which are developed model by model. The regression test database contains test cases for all components of the car. The production data comprises records from the garage about encountered problems. Test cases, i.e. component tests, can be selected according to the frequency of occurrence of problems or according to the costs that are related to failures in a certain component.

4. Customer Relationship Management (CRM) tools: This scenario describes a set of processes rather than a product. Test cases describe specific components of the processes, e.g. a help desk function. The production data contains all instances of the described processes containing also information of the output. So the test case characteristics, in this scenario also education/training item characteristics, can be selected according to such criteria as error-proneness or revenue relevance.

In the following, an exemplary application environment for the invention in the field of car manufacturing and sales will be described in more detail.

The following is an excerpt of a business process database typically provided by an above mentioned general ledger. The different business process positions shown here, i.e. sale by cash or credit and leasing of a car product identified by its product name ‘VW Golf’ etc. are ordered by means of a unique identifier ‘ID’ shown in the first column. The fourth column contains customer identification data and the fifth column revenue data for each of the positions.

1. General Ledger

| | | | | | |
|---|---|---|---|---|---|
| ID | Business Process | Product | Customer | Revenue | . . . |

| | | | | |
|---|---|---|---|---|
| 1 | Sale—Cash | VW Golf | DE4711 | 50,000 |
| 2 | Leasing | VW Passat | DE4712 | 20,000 |
| 3 | Sale—Credit | VW Passat | DE4747 | 60,000 |
| 4 | Sale—Cash | VW Polo | DE0815 | 20,000 |
| 5 | Sale—Cash | VW Golf | DE4700 | 60,000 |
| . . . | | | | |

Besides the above business data, it is assumed that the general ledger contains additional data depicted in the next table, i.e. in the present example business performance data for the processes depicted above like the time spent in hours for settling each of the positions and the respective customer satisfaction which can be obtained by often used questionnaires delivered together with the underlying business documents handed over to the customer together with the sold product.

1.a. Additional Data, e.g. Business Performance

| | | Time spent | Customer | |
|---|---|---|---|---|
| ID | Customer | (hours) | Satisfaction | . . . |
| 1 | DE4711 | 10 | 0.7 | |
| 2 | DE4712 | 2 | 0.5 | |
| 3 | DE4747 | 20 | 0.9 | |
| . . . | | | | |

The following table illustrates exemplary assessment criteria used to evaluate the collected fulfillment activity information shown in the above two tables. Particularly shown are two different criteria for the analysis, a first based on the business process itself, and the second based on a respective product.

2. Assessment Criteria

Scope: All data of the last 12 months

| Analyze per | Occurrence | Revenue | Time spent | . . . |
|---|---|---|---|---|
| Business Process | X | X | X | |
| Product | X | | | |
| . . . | | | | |

Typical results obtained by an analysis based on the above assessment criteria are shown in the following table. So, occurrence per business process (BP) and per product (P) is analyzed, also revenue per business process and time spent per business process. In particular, this analysis shown here sums up the values provided in the general ledger and the additional database for the given criteria.

3. Analysis Result

| | Occurrence | Revenue | Time spent | . . . |
|---|---|---|---|---|
| BP: Sale—Cash | 250 | 15,000,000 | 500 | |
| BP: Sale—Credit | 300 | 7,000,000 | 1.500 | |
| BP: Leasing | 120 | 9,000,000 | 750 | |
| BP: . . . | | | | |
| P: VW Polo | 200 | | | |
| P: VW Golf | 500 | | | |
| P: VW Passat | 100 | | | |
| P: . . . | | | | |
| . . . | | | | |

The following is an excerpt of a test case database. The test cases shown here have a unique identifier ‘ID’ as shown in the first column. The following columns describe the test case in a parameterized manner in accordance to the business processes which are stored in the general ledger database.

Field entries with a value ‘variable’ are not fixed but can be set to specific needs.

4. Test Case Database

| | | | | |
|---|---|---|---|---|
| ID | Business Process | Product | Customer | . . . |

| | | | |
|---|---|---|---|
| 1 | Sale—Cash | VW Polo | variable |
| 2 | Sale—Cash | VW Golf | variable |
| 3 | Sale—Cash | VW Passat | variable |
| 4 | Sale—Credit | variable | variable |
| 5 | Leasing | variable | variable |
| . . . | | | |

A test case database comprises a huge number of specific test cases. In prior art test environments it is hard to decide which test cases to select for the test case package that is used for the regression test.

The above problem is particularly addressed by the invention as test case criteria in combination with the general ledger provide the basis for automatically extracting specific test cases from that huge number of available test cases. This is how the real world link is provided.

5. Test Case Package Criteria

The result of the pre-described analysis is that the regression test should cover two criteria, namely these business processes which make up 80% of all business processes and, in addition, these business processes which generated a revenue of more than $10,000,000:

a) Cover 80% of business processes

b) Cover all business processes with Revenue>$10,000,000.

A particular advantage of the above-described mechanism therefore is that test case package criteria can be kept over the years but the set of test cases will dynamically change due to business changes of the real world environment.

6. Test Case Set+Validation Criteria

The first criterion thus leads to selection of the following two business processes:

A) Sales—Credit (300 occurrences=45%) represented by test case no. 4 and

B) Sales—Cash (250 occurrences=37%) represented by test case no. 1

The second criterion, in contrast to the above, leads to selection of the following business process:

A′) Sales—Cash (15,000,000) represented by test case no. 1

As a final result, a minimal Test Case Set should contain only two test cases, namely Test case no. 1 and Test case no. 4.

7. Test Report

Finally, the following table illustrates a test status report after test case (TC) no. 4 was processed:

| | | |
|---|---|---|
| Test cases to run | TC1 | |
| | TC4 | |
| Test cases completed | 1 of 2: | |
| | TC1 | |
| Coverage | Criterion a. | Not yet met: 37% of business |
| | | processes covered |
| | Criterion b. | Fully met: All business processes |
| | | with Revenue > $10,000,000 |
| | | covered |

The described mechanism provides the missing link allowing to measure the real regression test coverage and progress, looking beyond the rural number of test cases and keeping the volume of the regression test to an absolute minimum.

What is claimed is:

1. A method for generating regression test packages in a fulfillment management system, comprising the steps of
collecting fulfillment activity information;
defining a set of criteria for evaluating the collected fulfillment activity information;
evaluating the collected fulfillment activity information based on the set of criteria;
defining objectives for generating regression test packages; and
generating regression test packages based on the defined objectives and results of evaluating the collected fulfillment activity information.

2. The method of claim 1, comprising the further step of:
running at least one regression test using the generated regression test packages.

3. The method of claim 1, wherein the step of generating regression test packages is accomplished by combining existing test cases.

4. The method of claim 1, wherein the fulfillment activity information is collected from a general ledger database.

5. The method of claim 1, wherein the criteria include a number of occurrences.

6. The method of claim 1, wherein the criteria include an amount of revenue or profit by order or contract type.

7. The method of claim 1, wherein the criteria include material classes.

8. The method of claim 1, wherein the criteria include customer classes.

9. The method of claim 1, wherein the criteria include a number of processing errors.

10. The method of claim 1, wherein the criteria include customer satisfaction.

11. The method of claim 1, wherein the fulfillment activity information is enriched with data from a performance database.

12. The method of claim 1, wherein the fulfillment activity information is enriched with data from a maintenance database.

13. The method of claim 1, wherein the fulfillment activity information is enriched with data from an error database.

14. The method of claim 1, wherein the fulfillment activity information is enriched with data from a customer satisfaction database.

15. The method of claim 1, comprising the step defining a customer class or a material class and wherein the step of evaluating the collected fulfillment activity information includes evaluating production data of a defined period of time according to given criteria.

16. The method of claim 15, wherein the given criteria include a number of occurrences.

17. The method of claim 15, wherein the given criteria include an amount of revenue or profit by order or contract type.

18. The method of claim 15, wherein the given criteria include a number of occurrences per customer class.

19. The method of claim 15, wherein the given criteria include a number of occurrences per material class.

20. The method of claim 1, wherein the objectives for generating regression test packages include a number of overall test cases.

21. The method of claim 1, wherein the objectives for generating regression test packages include a percentage of coverage of order types.

22. The method of claim 1, wherein the objectives for generating regression test packages include a percentage of revenue.

23. The method of claim 1, wherein the objectives for generating regression test packages include a percentage of profit.

24. The method of claim 1, wherein the objectives for generating regression test packages include error-prone sections.

25. The method of claim 1, comprising the step of combining appropriate test scenarios of an order or contract type from a provided test case database.

26. The method of claim 1, comprising the step of combining appropriate test scenarios of a customer from a provided test case database.

27. The method of claim 1, comprising the step of combining appropriate test scenarios of a material from a provided test case database.

28. The method of claim 1, comprising the step of processing current status reports during a regression test by providing actual data according to the defined objectives.

29. A data processing program for execution in a data processing system comprising software code portions for performing a method according to claim 1 when the program is run on the computer.

30. A computer program product stored on a computer usable medium, comprising computer readable program means for causing a computer to perform a method according to claim 1 when the program is run on the computer.

31. A fulfillment system comprising a regression test package generator for generating regression test packages, operating in accordance with the method of claim 1.

32. A system according to claim 31, where the regression test package generator comprises means for collecting fulfillment activity information, means for defining a set of criteria for evaluating the collected fulfillment activity information, means for evaluating the collected fulfillment activity information based on the set of criteria, and means for defining objectives for generating regression test packages.

33. A system according to claim 31, comprising a general ledger database providing the fulfillment activity data.

34. A system according to claim 31, comprising means for processing status reports for currently running test cases.
